(19) United States
(12) Patent Application Publication
(10) Pub. No.: US 2002/0017667 A1
(43) Pub. Date: Feb. 14, 2002

(54) Ferroelectric memory and method of fabricating the same

(75) Inventors: Tatsuya Shimoda, Suwa-shi (JP); Koichi Oguchi, Suwa-shi (JP); Eiji Natori, Chino-shi (JP); Kazumasa Hasegawa, Fujimi-cho (JP); Atsushi Takakuwa, Shiojiri-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 09/892,872

(22) Filed: Jun. 28, 2001

(30) Foreign Application Priority Data
Jun. 30, 2000 (JP) 2000-199987

(51) Int. Cl. H01L 21/00; H01L 21/8242; H01L 29/76

(52) U.S. Cl. 257/295; 438/3; 438/240

(57) ABSTRACT

A ferroelectric memory according to the present invention includes a passive matrix array in which memory cells formed of ferroelectric capacitors are arranged, and a peripheral circuit for the passive matrix array. The passive matrix array is formed of a passive matrix array microchip, and the peripheral circuit such as a word line driver circuit or a bit line driver circuit is formed on a peripheral circuit substrate, thereby integrating the passive matrix array microchip on the peripheral circuit substrate. Since this allows the passive matrix array and the peripheral circuit therefor to be separately fabricated, the peripheral circuit is not adversely affected when fabricating the passive matrix array, thereby decreasing the degree of limitation in the fabrication process.

Japanese Patent Application No. 2000-199987, filed on Jun. 30, 2000, is hereby incorporated by reference in its entirety.

### BACKGROUND OF THE INVENTION

1. Field of the Invention

The present invention relates to a ferroelectric memory using a ferroelectric material for memory cells. More particularly, the present invention relates to a passive address ferroelectric memory in which each memory cell is formed by one ferroelectric capacitor instead of using a cell transistor.

2. Description of Related Art

Conventionally, this type of ferroelectric memory is disclosed in International Patent Application No. WO99/12170 and Japanese Patent Application Laid-open No. 9-116107, for example. Such a ferroelectric memory includes a passive matrix array in which memory cells formed of ferroelectric capacitors are arranged in rows and columns, and peripheral circuits for performing data read or write operations for each memory cell and the like.

The passive matrix array includes a ferroelectric film 1, a plurality of upper electrodes 2 secured on the upper side of the ferroelectric film 1, arranged in the X direction, and a plurality of lower electrodes 3 secured on the lower side of the ferroelectric film 1, arranged in the Y direction. Memory cells 4 formed of ferroelectric capacitors are formed at each intersection point between the electrodes 2 and 3. Data is read from or written into each memory cell 4 by peripheral circuits (not shown).

Such a conventional ferroelectric memory is fabricated by integrating the passive matrix array and the peripheral circuits on a single substrate in one plane. Part of fabrication steps for the ferroelectric memory is described below with reference to FIGS. 26A, 26B, and 26C.

FIG. 26A is a cross-sectional view showing the formation of a MOS transistor which makes up the peripheral circuits. In FIG. 26A, a silicon substrate 11, a source region 12, a drain region 13, a gate insulating film 14, a gate electrode 15, a buried plug 16, a LOCOS oxide film 17, and interlayer dielectrics 18 and 19 are illustrated.

FIG. 26B is a cross-sectional view showing the formation of a passive matrix array. The formation procedure is as follows. As shown in FIG. 26B, a metal film is formed on the interlayer dielectric 19. A lower electrode 21 is formed by etching the metal film. A ferroelectric film 22 is formed on the lower electrode 21. A metal film is formed on the ferroelectric film 22. An upper electrode 23 is formed by etching the metal film. As a material for the ferroelectric film 22, PZT (PbZr₁₋ₓTiₓO₃), SBT (SrBi₂Ta₂O₉), or the like is used.

FIG. 26C is a cross-sectional view showing the formation of a protective layer. The formation procedure is as follows. As shown in FIG. 26C, a protective layer 24 is formed on the upper electrode 23 and the like. Through-holes are formed in the protective layer 24 in the direction of the thickness of the protective layer 24. A metal film is formed on the protective layer 24. A wiring layer 25 is formed by etching the metal film. A protective layer 26 is formed on the wiring layer 25.

During the formation of the passive matrix array shown in FIG. 26B, a high temperature treatment (at about 700° C.) is performed in an oxygen atmosphere for forming the ferroelectric film 22. This causes the MOS transistor formed in advance to deteriorate. In order to compensate for this deterioration, a thermal treatment is performed in a hydrogen atmosphere in the succeeding step. However, this causes the ferroelectric characteristics of the ferroelectric film 22 to deteriorate. Therefore, the completed device must be operated at a point of compromise between these deteriorations.

Moreover, the component of the ferroelectric film 22 is diffused into a region of the MOS transistor during the formation of the ferroelectric film 22, thereby decreasing the performance of the MOS transistor.

Therefore, in the case of integrating the passive matrix array and the peripheral circuits on a single substrate such as in the case of fabricating a conventional ferroelectric memory, the fabrication process is limited to a large extent as described above.

### SUMMARY OF THE INVENTION

The present invention is devised in the light of the above problems and has as an objective thereof the provision of a ferroelectric memory capable of reducing the degree of limitations in the fabrication process, and a method of fabricating the same.

In order to solve the above problems and to achieve the objective of the present invention, the present invention according to claims 1 to 19 has the following features.

Specifically, A ferroelectric memory according to claim 1 comprises: a passive matrix array in which memory cells formed of ferroelectric capacitors are arranged; and a peripheral circuit for the passive matrix array, wherein the passive matrix array is formed on a microstructure, and the peripheral circuit is formed on a substrate; and the microstructure is integrated on the substrate.

A ferroelectric memory according to claim 2 comprises: a passive matrix array in which memory cells formed of ferroelectric capacitors are arranged; and a peripheral circuit for the passive matrix array, wherein the passive matrix array is formed on a substrate; the peripheral circuit is formed on a microstructure; and the microstructures is integrated on the substrate.

A ferroelectric memory according to claim 3 comprises: a passive matrix array in which memory cells formed of ferroelectric capacitors are arranged; and a peripheral circuit for the passive matrix array, wherein the passive matrix array is formed on a first microstructure; the peripheral circuit is formed on a second microstructure; and the first and second microstructures are integrated on a substrate.

According to claim 4, in the ferroelectric memory as shown in claim 1, 2 or 3, a plurality of passive matrix arrays may be formed on the microstructures; and a plurality of peripheral circuits may be formed on the microstructures.

According to claim 5, in the ferroelectric memory as shown in any one of claims 1 to 4, a recess portion in which the microstructure is provided may be formed in the substrate; and the microstructure may be provided in the recess portion and integrated on the substrate.

According to claim 6, in the ferroelectric memory as showin in claim 5, the substrate may be formed by transfer-molding a photocurable resin.

A ferroelectric memory according to claim 7 comprises: a passive matrix array in which memory cells formed of ferroelectric capacitors are arranged; a peripheral circuit for the passive matrix array; and a plurality of pairs of the passive matrix array formed on a first microstructure and the peripheral circuit formed on a second microstructure, wherein at least one of the pairs is provided on each side of a substrate.

A ferroelectric memory according to claim 8 comprises: a passive matrix array in which memory cells formed of ferroelectric capacitors are arranged; a peripheral circuit for the passive matrix array; and an associated circuit having the same function as the ferroelectric memory or a different function from the ferroelectric memory, wherein the passive matrix array, the peripheral circuit and the associated circuit are formed on each of a plurality of microstructures; and the microstructures are integrated on a single substrate.

A ferroelectric memory according to claim 9 comprises: a passive matrix array in which memory cells formed of ferroelectric capacitors are arranged; and a peripheral circuit for the passive matrix array, wherein the passive matrix array and the peripheral circuit are integrated on a single microstructure.

A ferroelectric memory according to claim 10 comprises: a passive matrix array in which memory cells formed of ferroelectric capacitors are arranged; and a peripheral circuit for the passive matrix array, wherein the passive matrix array is formed on a first microstructure; the peripheral circuit is formed on a second microstructure which is larger than the first microstructure; and the first microstructure is provided in a part of the second microstructure to be integrated.

A ferroelectric memory according to claim 11 comprises: a passive matrix array in which memory cells formed of ferroelectric capacitors are arranged; and a peripheral circuit for the passive matrix array, wherein the passive matrix array is formed on each of a plurality of microstructures, and the microstructures are provided in layers to be integrated in a substrate.

According to claim 12, there is provided a method of fabricating a ferroelectric memory which includes: a passive matrix array in which memory cells formed of ferroelectric capacitors are arranged; and a peripheral circuit for the passive matrix array, wherein the passive matrix array is formed on a microstructure, and the peripheral circuit is formed on a substrate; and the microstructure is integrated on the substrate.

According to claim 13, there is provided a method of fabricating a ferroelectric memory which includes: a passive matrix array in which memory cells formed of ferroelectric capacitors are arranged; and a peripheral circuit for the passive matrix array, wherein the passive matrix array is formed on a substrate; the peripheral circuit is formed on a microstructure; and the microstructure is integrated on the substrate.

According to claim 14, there is provided a method of fabricating a ferroelectric memory which includes: a passive matrix array in which memory cells formed of ferroelectric capacitors are arranged; and a peripheral circuit for the passive matrix array, wherein the passive matrix array is formed on a first microstructure; the peripheral circuit is formed on a second microstructure; and the first and second microstructures are integrated on a substrate.

According to claim 15, in the method of fabricating a ferroelectric memory as shown in any one of claims 12 to 14, a substrate having a recess portion which corresponds to a shape of the microstructure may be provided; and the microstructure may be provided in the corresponding recess portion in the substrate to be integrated.

According to claim 16, in the method of fabricating a ferroelectric memory as shown in claim 15, the microstructure may be provided in the recess portion in the substrate by providing a fluid which contains the microstructure to a surface of the substrate.

According to claim 17, there is provided a method of fabricating a ferroelectric memory which includes: a passive matrix array in which memory cells formed of ferroelectric capacitors are arranged; and a peripheral circuit for the passive matrix array, wherein a plurality of pairs of the passive matrix array formed on a first microstructure and the peripheral circuit formed on a second microstructure are provided: and at least one of the pairs is integrated on each side of a substrate.

According to claim 18, there is provided a method of fabricating a ferroelectric memory which includes: a passive matrix array in which memory cells formed of ferroelectric capacitors are arranged; and a peripheral circuit for the passive matrix array, wherein the passive matrix array is formed on a first microstructure; the peripheral circuit is formed on a second microstructure which is larger than the first microstructure; and the first microstructure is provided in a part of the second microstructure to be integrated.

According to claim 19, there is provided a method of fabricating a ferroelectric memory which includes: a passive matrix array in which memory cells formed of ferroelectric capacitors are arranged; and a peripheral circuit for the passive matrix array, wherein the passive matrix array is formed on each of a plurality of microstructures; and the microstructures are provided in layers to be integrated in a substrate.

### BRIEF DESCRIPTION OF THE DRAWINGS

FIG. 1 is a plan view showing a ferroelectric memory according to a first embodiment of the present invention.

FIG. 2 is a cross-sectional view along the line A-A shown in FIG. 1, in which only the cross section of a passive matrix array microchip is illustrated, with others being omitted.

FIG. 3 is a plan view showing a modification example of the first embodiment.

FIG. 4 is a plan view showing a ferroelectric memory according to a second embodiment of the present invention.

FIG. 5 is a cross-sectional view along the line B-B shown in FIG. 4, in which only the cross section of a passive matrix array microchip is illustrated and others are omitted.

FIG. 6 is a plan view showing a modification example of the second embodiment.

FIG. 7 is a plan view showing a ferroelectric memory according to a third embodiment of the present invention.

FIG. 8 is a cross-sectional view along the line C-C shown in FIG. 7, in which only the cross section of a word line driver circuit microchip is illustrated, with others being omitted.

FIG. 9 is a plan view showing a ferroelectric memory according to a fourth embodiment of the present invention.

FIG. 10 is a plan view showing a ferroelectric memory according to a fifth embodiment of the present invention.

FIG. 11 is a cross-sectional view along the line D-D shown in FIG. 10.

FIG. 12 is a plan view showing a ferroelectric memory according to a sixth embodiment of the present invention.

FIG. 13 is a plan view showing a modification example of the sixth embodiment.

FIG. 14 is a plan view showing a ferroelectric memory according to a seventh embodiment of the present invention.

FIG. 15 is a cross-sectional view along the line E-E shown in FIG. 14.

FIG. 16 is a plan view showing a ferroelectric memory according to an eighth embodiment of the present invention.

FIG. 17 is a plan view showing a ferroelectric memory according to a ninth embodiment of the present invention.

FIG. 18 is a plan view showing a ferroelectric memory according to a tenth embodiment of the present invention.

FIG. 19 is a plan view showing a ferroelectric memory according to an eleventh embodiment of the present invention.

FIG. 20 is a plan view showing a ferroelectric memory according to a twelfth embodiment of the present invention.

FIG. 21 is across-sectional view along the line F-F shown in FIG. 20, in which only the cross section of a passive matrix array microchip is illustrated, with others being omitted.

FIG. 22 is a cross-sectional view showing a ferroelectric memory according to a thirteenth embodiment of the present invention.

FIG. 23 is a cross-sectional view showing a ferroelectric memory according to a fourteenth embodiment of the present invention.

FIG. 24 is a plan view showing the structure of a passive matrix array.

FIG. 25 is a cross-sectional view along the line G-G shown in FIG. 24.

FIGS. 26A, 26B, and 26C are views for describing fabrication steps for a conventional ferroelectric memory.

### DETAILED DESCRIPTION OF THE EMBODIMENTS

Embodiments of the present invention are described below with reference to the drawings.

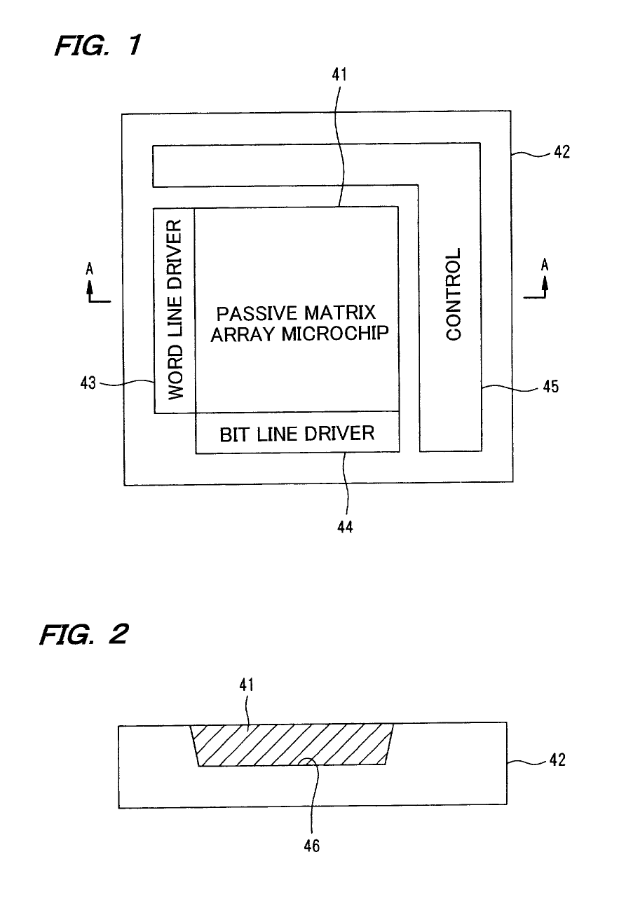

A first embodiment of the ferroelectric memory of the present invention is described below with reference to FIGS. 1 and 2. In the ferroelectric memory according to the first embodiment, a passive matrix array microchip 41 is integrated on a peripheral circuit substrate 42, as shown in FIGS. 1 and 2.

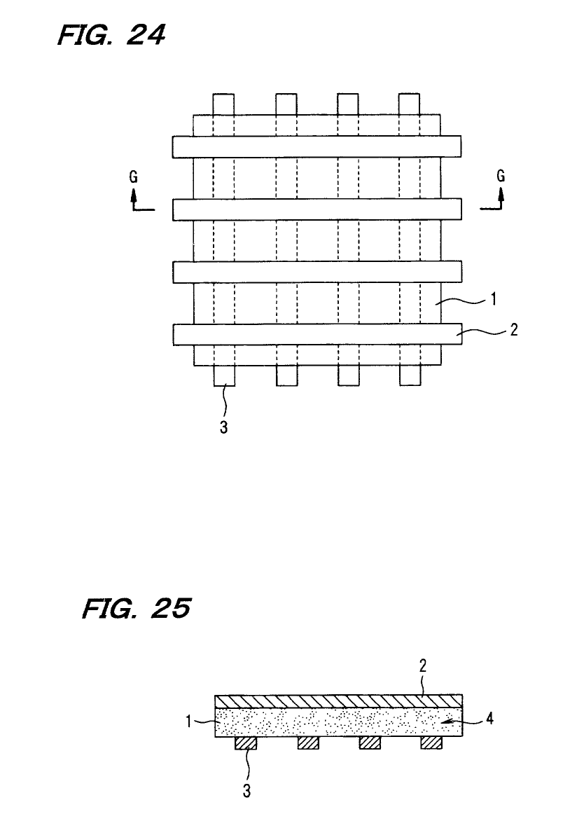

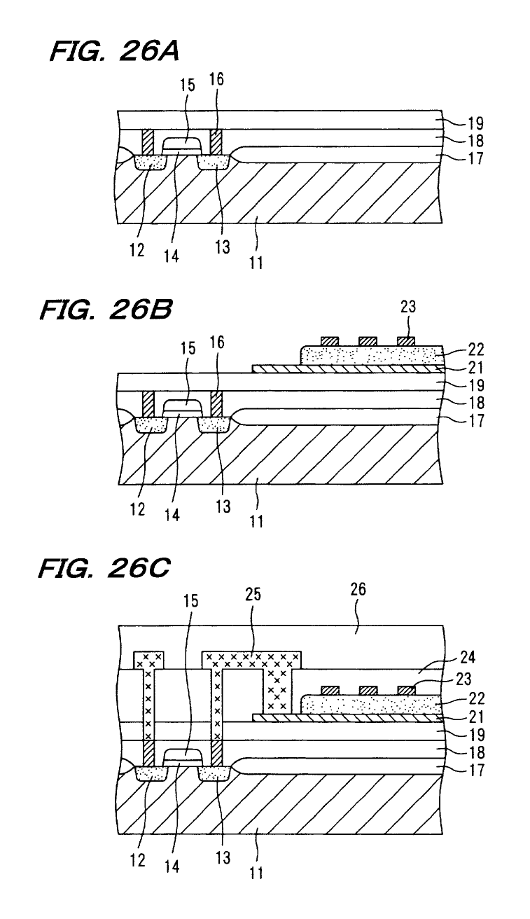

The passive matrix array microchip 41 is a microchip of a passive matrix array having a structure shown in FIGS. 24 and 25. A tapered recess portion 46 is formed at approximately the center of the peripheral circuit substrate 42. The passive matrix array microchip 41 is positioned in the recess portion 46 and integrated on the peripheral circuit substrate 42. This passive matrix array microchip is provided by forming a passive matrix array on a silicon substrate, a plastic sheet, a glass substrate, a ceramic substrate, or the like, and performing cutting or anisotropic etching to provide a microstructure. A word line driver circuit 43, a bit line driver circuit (including sense amplifier) 44, and a control circuit 45 are formed on the peripheral circuit substrate 42 as peripheral circuits for the passive matrix array microchip 41, so as to enclose the area in which the passive matrix array microchip 41 is integrated.

In each of the following embodiments, “a passive matrix array” refers to a memory cell array having the structure shown in FIGS. 24 and 25.

As the peripheral circuit substrate 42, a silicon wafer (silicon substrate) or the like may be used. In each of the following embodiments, substrates illustrated above may be used.

In each of the following embodiments, “a microchip” is formed by forming circuits on a silicon substrate, a plastic sheet, a glass substrate, a ceramic substrate, or the like, and performing cutting or anisotropic etching to provide a microstructure.

An example of a method of fabricating the ferroelectric memory having the above structure according to the first embodiment is described below.

A passive matrix array is provided on the passive matrix array microchip 41 as a microstructure. The recess portion 46 for positioning the passive matrix array microchip 41 is formed at approximately the center of the peripheral circuit substrate 42. The word line driver circuit 43, the bit line driver circuit 44, and the control circuit 45 are formed around the recess portion 46.

The passive matrix array microchip 41 is positioned in the recess portion 46 formed in the peripheral circuit substrate 42. The passive matrix array microchip 41 is integrated on the peripheral circuit substrate 42 through specific processing, including electrically connecting the passive matrix array microchip 41 to the word line driver circuit 43, the bit line driver circuit 44, and the like.

As described above, according to the first embodiment, the passive matrix array and the peripheral circuits therefor can be separately fabricated. Therefore, the peripheral circuits are not adversely affected when fabricating the passive matrix array, thereby decreasing the degree of limitation in the fabrication process.

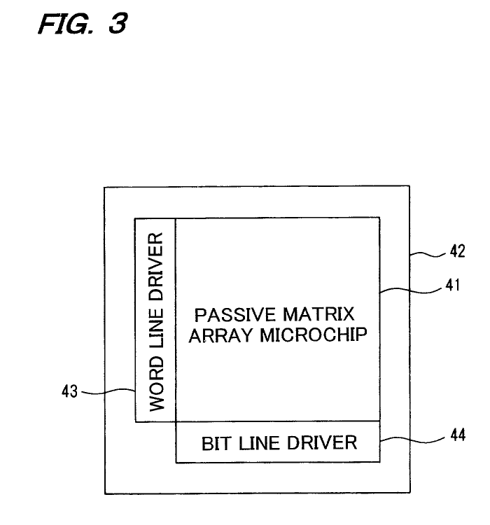

FIG. 3 shows a modification example of the first embodiment. In this modification example, the control circuit 45 formed on the peripheral circuit substrate 42 shown in FIG. 1 is omitted. The structure of other components of this modification example is the same as the structure shown in FIG. 1. Therefore, the same components are represented by using the same symbols, and detailed description of these components is omitted.

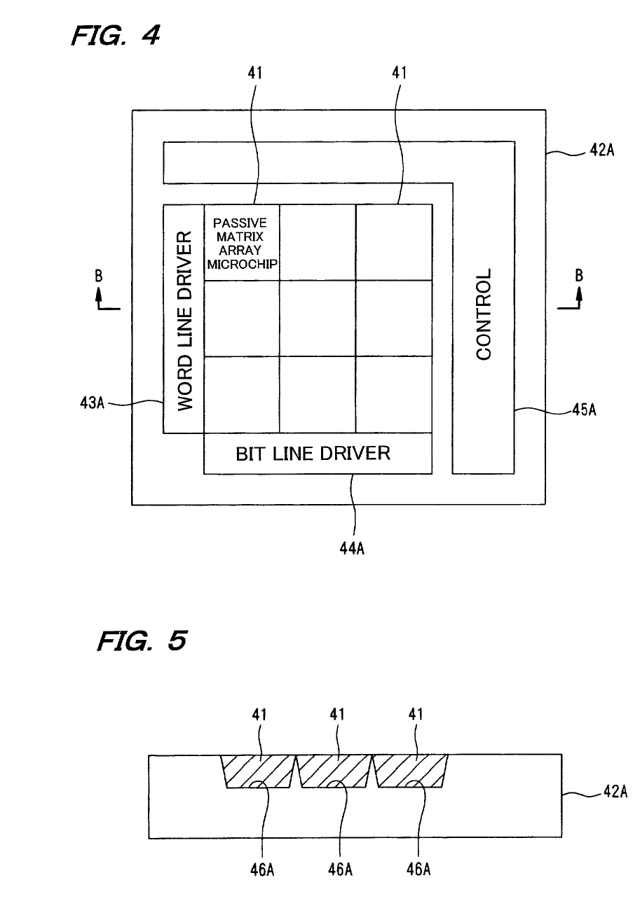

A second embodiment of the ferroelectric memory of the present invention is described below with reference to FIGS. 4 and 5.

The ferroelectric memory according to the second embodiment aims at increasing the size of the first embodiment shown in FIG. 1. As shown in FIG. 4, a large-sized peripheral circuit substrate 42A is used in place of the peripheral circuit substrate 42 shown in FIG. 1. A plurality of (nine in this example) passive matrix array microchips 41 is integrated on the peripheral circuit substrate 42A.

Accompanied by this, a word line driver circuit 43A, a bit line driver circuit (including sense amplifier) 44A, and a control circuit 45A formed on the peripheral circuit substrate 42A are also increased in size.

An example of a method of fabricating the ferroelectric memory having the above structure according to the second embodiment is described below.

A plurality of passive matrix array microchips 41 as microstructures is provided as the passive matrix arrays. A plurality of recess portions 46A for positioning the passive matrix array microchip 41 is formed at approximately the center of the peripheral circuit substrate 42A. The word line driver circuit 43A, the bit line driver circuit 44A, and the control circuit 45A are formed so as to enclose the recess portions 46A.

The passive matrix array microchips 41 are positioned in each recess portion 46A formed in the peripheral circuit substrate 42A. A plurality of passive matrix array microchips 41 is integrated on the peripheral circuit substrate 42A through specific processing, including electrically connecting the passive matrix array microchips 41 to the word line driver circuit 43A, the bit line driver circuit 44A, and the like.

As described above, according to the second embodiment, the passive matrix array and the peripheral circuits therefor can be separately fabricated. Therefore, the peripheral circuits are not adversely affected when fabricating the passive matrix array, thereby decreasing the degree of limitation in the fabrication process.

According to the second embodiment, since a plurality of passive matrix array microchips 41 is provided, a large-scale ferroelectric memory can be fabricated.

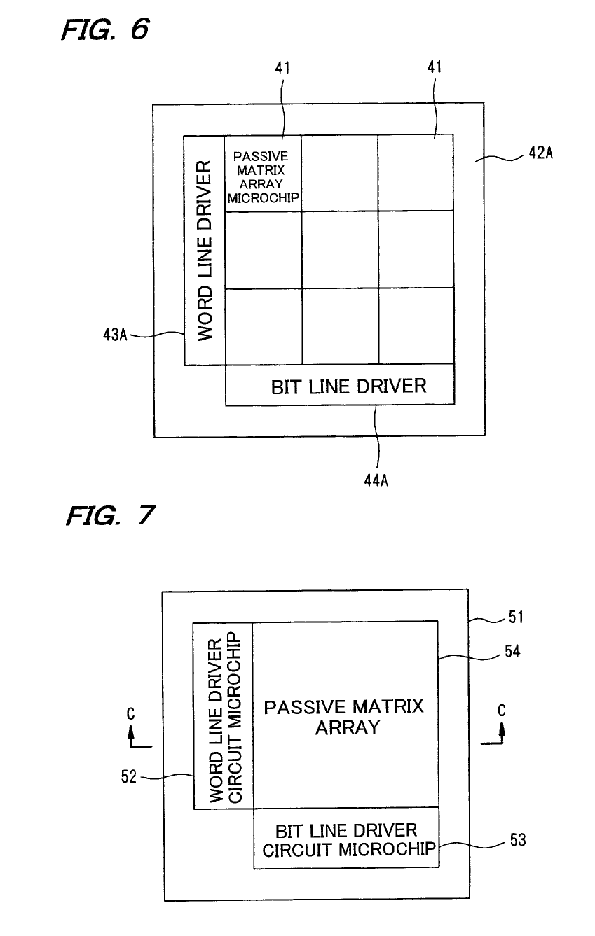

FIG. 6 shows a modification example of the second embodiment. In this modification example, the control circuit 45A formed on the peripheral circuit substrate 42A shown in FIG. 4 is omitted. The structures of other components of this modification example are the same as the structure shown in FIG. 1. Therefore, the same components are represented by using the same symbols, and detailed description of these components is omitted.

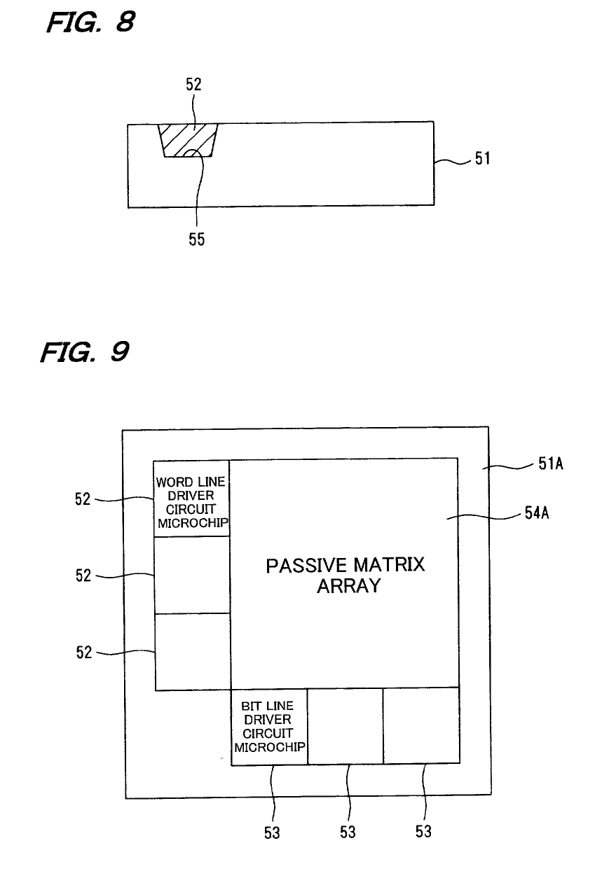

A third embodiment of the ferroelectric memory of the present invention is described below with reference to FIGS. 7 and 8.

In the ferroelectric memory according to the third embodiment, a word line driver circuit microchip 52 and a bit line driver circuit microchip 53 are integrated on a passive matrix array substrate 51, as shown in FIGS. 7 and 8.

A passive matrix array 54 is formed at approximately the center of the passive matrix array substrate 51. The word line driver circuit microchip 52 and the bit line driver circuit microchip 53 are provided by forming a word line driver circuit and a bit line driver circuit for performing read or write operation for each memory cell of the passive matrix array on a silicon substrate or the like, and performing cutting or anisotropic etching to provide microstructures.

An example of a method of fabricating the ferroelectric memory having the above structure according to the third embodiment is described below.

The word line driver circuit microchip 52 and the bit line driver circuit microchip 53 are provided. The passive matrix array 54 is formed at approximately the center of the passive matrix array substrate 51. A recess portion 55 for positioning the word line driver circuit microchip 52 and a recess portion (not shown) for positioning the bit line driver circuit microchip 53 are formed around the passive matrix array 54.

The word line driver circuit microchip 52 and the bit line driver circuit microchip 53 are positioned in the recess portion 55 and the like formed in the passive matrix array substrate 51. The word line driver circuit microchip 52 and the bit line driver circuit microchip 53 are integrated on the passive matrix array substrate 51 through specific processing including electrically connecting these microchips to the passive matrix array 54.

As described above, according to the third embodiment, the passive matrix array and the peripheral circuits therefor can be separately fabricated. Therefore, the peripheral circuits are not adversely affected when fabricating the passive matrix array, thereby decreasing the degree of limitation in the fabrication process.

A fourth embodiment of the ferroelectric memory of the present invention is described below with reference to FIG. 9.

The ferroelectric memory according to the fourth embodiment aims at increasing the size of the third embodiment shown in FIG. 7. As shown in FIG. 9, a large-sized passive matrix array substrate 51A is used in place of the passive matrix array substrate 51 shown in FIG. 7. A plurality of word line driver circuit microchips 52 and a plurality of bit line driver circuit microchips 53 are integrated on the passive matrix array substrate 51A. Accompanied by this, a passive matrix array 54A formed on the passive matrix array substrate 51A is also increased in size.

An example of a method of fabricating the ferroelectric memory having the above structure according to the fourth embodiment is described below.

A plurality of word line driver circuit microchips 52 and a plurality of bit line driver circuit microchips 53 are respectively provided. The passive matrix array 54A is formed at approximately the center of the passive matrix array substrate 51A. A plurality of recess portions (not shown) for positioning the word line driver circuit microchips 52 and a plurality of recess portions (not shown) for positioning the bit line driver circuit microchips 53 are formed around the passive matrix array 54A.

A plurality of word line driver circuit microchips 52 and a plurality of bit line driver circuit microchips 53 are positioned in each recess portion formed in the passive matrix array substrate 51A. A plurality of word line driver circuit microchips 52 and a plurality of bit line driver circuit microchips 53 are integrated on the passive matrix array substrate 51A through specific processing, including electrically connecting these microchips to the passive matrix array 54A.

As described above, according to the fourth embodiment, the passive matrix array and the peripheral circuits therefor can be separately fabricated. Therefore, the peripheral circuits are not adversely affected when fabricating the passive matrix array, thereby decreasing the degree of limitation in the fabrication process.

According to the fourth embodiment, a plurality of word line driver circuit microchips 52 and the like are provided, whereby a large-scale ferroelectric memory can be fabricated.

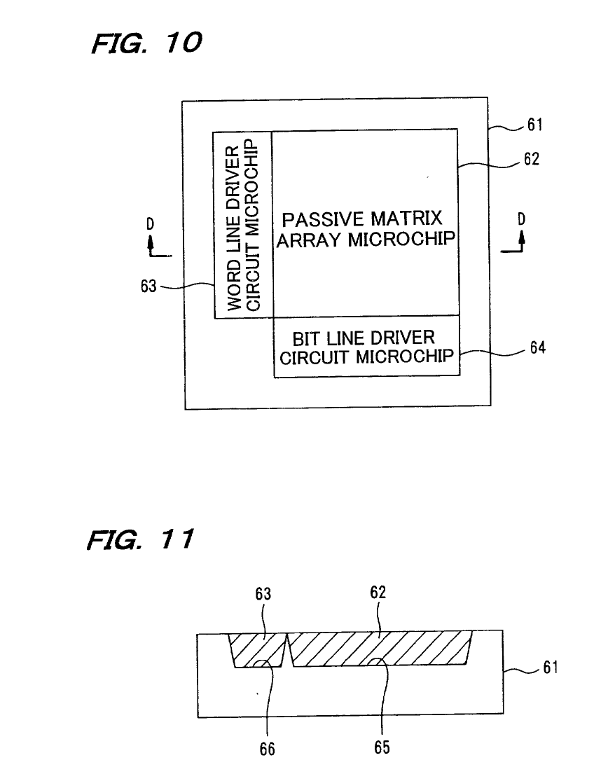

A fifth embodiment of the ferroelectric memory of the present invention is described below with reference to FIGS. 10 and 11.

In the ferroelectric memory according to the fifth embodiment, a passive matrix array microchip 62, a word line driver circuit microchip 63, and a bit line driver circuit microchip 64 are integrated on a substrate 61, as shown in FIGS. 10 and 11.

The passive matrix array microchip 62 is a microchip of a passive matrix array. The word line driver circuit microchip 63 and the bit line driver circuit microchip 64 are microchips of a word line driver circuit and a bit line driver circuit as peripheral circuits for performing read or write operation for each memory cell of the passive matrix array.

A recess portion 65 for positioning the passive matrix array microchip 62 is formed at approximately the center of the substrate 61. A recess portion 66 for positioning the word line driver circuit microchip 63 and a recess portion (not shown) for positioning the bit line driver circuit microchip 64 are formed around the recess portion 65. Each of the microchips 62 and 63 is positioned in each recess portion and integrated on the substrate 61.

An example of a method of fabricating the ferroelectric memory having the above structure according to the fifth embodiment is described below.

The passive matrix array microchip 62, the word line driver circuit microchip 63, and the bit line driver circuit microchip 64 are respectively provided. The recess portion 65 for positioning the passive matrix array microchip 62 is formed at the center of the substrate 61. The recess portion 66 for positioning the word line driver circuit microchip 63 and the recess portion (not shown) for positioning the bit line driver circuit microchip 64 are formed around the recess portion 65.

The passive matrix array microchip 62, the word line driver circuit microchip 63, and the bit line driver circuit microchip 64 are positioned in each recess portion formed in the substrate 61. Specific processing including electrically connecting the word line driver circuit microchip 63 and the bit line driver circuit microchip 64 to the passive matrix array microchip 62 are performed, thereby integrating these microchips on the substrate 61.

As described above, according to the fifth embodiment, the passive matrix array and the peripheral circuits therefor can be separately fabricated. Therefore, the peripheral circuits are not adversely affected when fabricating the passive matrix array, thereby decreasing the degree of limitation in the fabrication process.

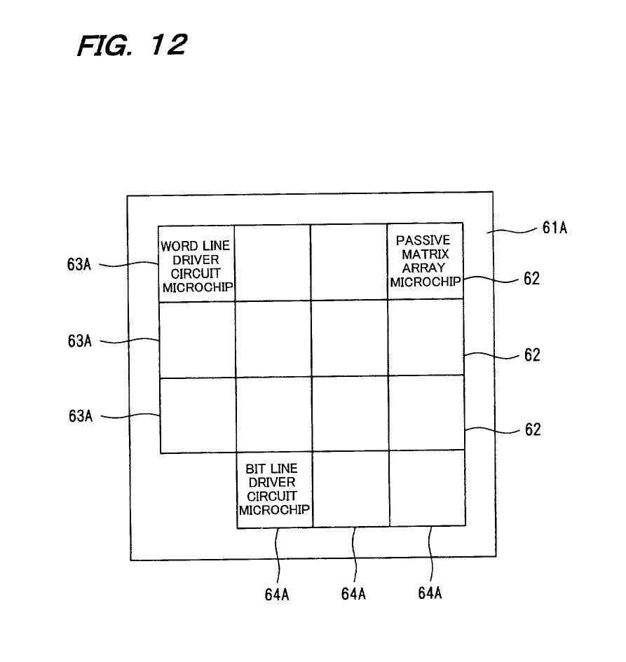

A sixth embodiment of the ferroelectric memory of the present invention is described below with reference to FIG. 12.

The ferroelectric memory according to the sixth embodiment aims at increasing the size of the fifth embodiment shown in FIG. 10. As shown in FIG. 12, a large-sized substrate 61A is used in place of the substrate 61 shown in FIG. 10. A plurality of (nine in this example) passive matrix array microchips 62 is integrated at approximately the center of the substrate 61A. A plurality of word line driver circuit microchips 63A and a plurality of bit line driver circuit microchips 64A are integrated on the substrate 61A around the passive matrix array microchips 62.

An example of a method of fabricating the ferroelectric memory having the above structure according to the sixth embodiment is described below.

A plurality of passive matrix array microchips 62, a plurality of word line driver circuit microchips 63A, and a plurality of bit line driver circuit microchips 64A are provided. Recess portions for positioning each of the passive matrix array microchips 62, the word line driver circuit microchips 63, and the bit line driver circuit microchips 64 are formed in the substrate 61A.

A plurality of passive matrix array microchips 62, a plurality of word line driver circuit microchips 63, and a plurality of bit line driver circuit microchips 64 are positioned in each recess portion formed in the substrate 61A. Specific processing, including electrically connecting a plurality of word line driver circuit microchips 63 and a plurality of bit line driver circuit microchips 64 to a plurality of passive matrix array microchips 62, is performed, thereby integrating these microchips on the substrate 61A.

As described above, according to the sixth embodiment, the passive matrix array and the peripheral circuits therefor can be separately fabricated. Therefore, the peripheral circuits are not adversely affected when fabricating the passive matrix array, thereby decreasing the degree of limitation in the fabrication process.

According to the sixth embodiment, a plurality of passive matrix array microchips 62, a plurality of word line driver circuit microchips 63A, and the like are provided, whereby a large-scale ferroelectric memory can be fabricated.

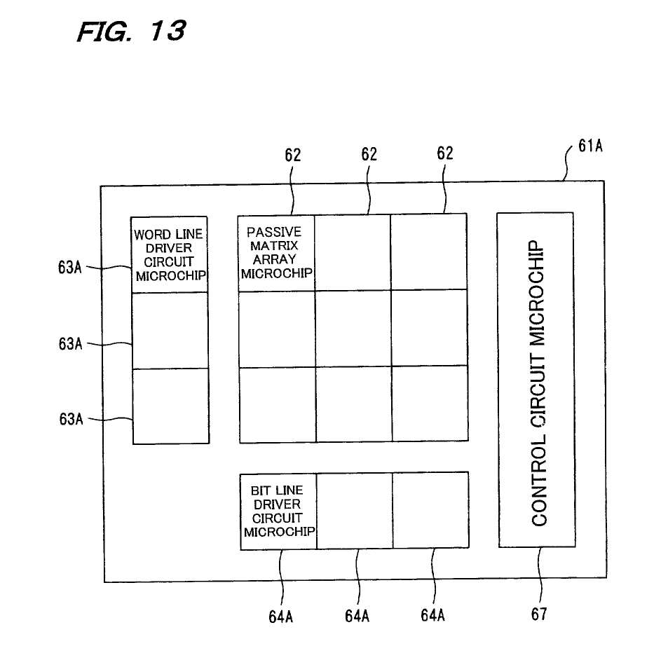

FIG. 13 shows a modification example of the sixth embodiment. In this modification example, a control circuit microchip 67 which is a microchip for a control circuit is additionally integrated on the substrate 61A shown in FIG. 12. The structure of other components of this modification example are the same as the structure shown in FIG. 12. Therefore, the same components are represented by using the same symbols, and detailed description of these components is omitted.

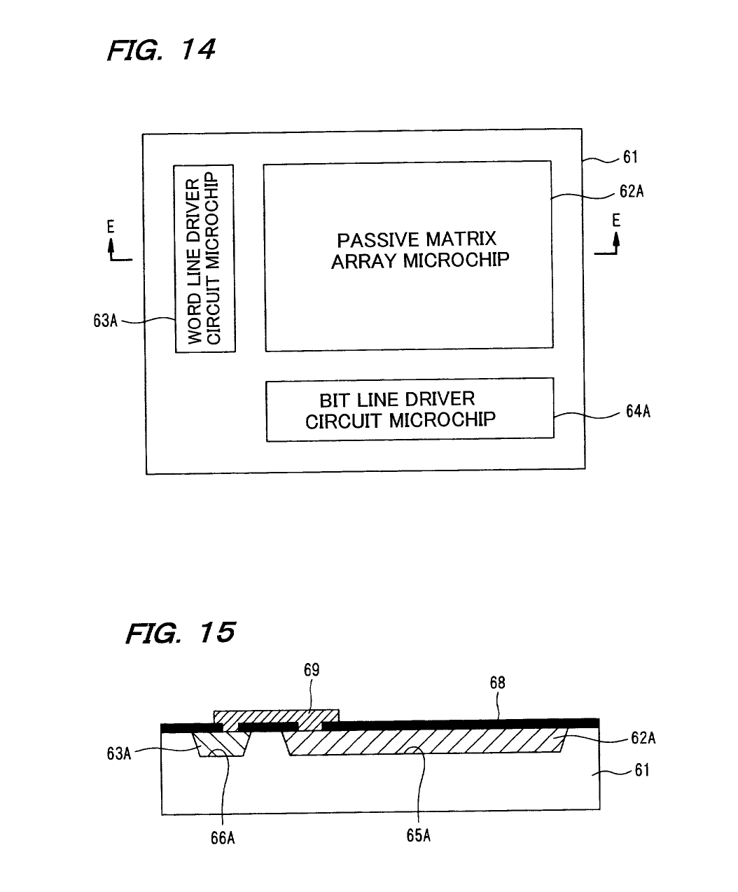

A seventh embodiment of the ferroelectric memory of the present invention is described below with reference to FIGS. 14 and 15.

In the ferroelectric memory according to the seventh embodiment, a passive matrix array microchip 62, a word line driver circuit microchip 63A, and a bit line driver circuit microchip 64A, each having a different shape as shown in FIG. 14 are respectively used in place of the passive matrix array microchip 62, the word line driver circuit microchip 63, and the bit line driver circuit microchip 64 of the fifth embodiment shown in FIG. 10. Each of these microchips is integrated on the substrate 61.

A recess portion 65A for positioning the passive matrix array microchip 62A is formed at approximately the center of the substrate 61. A recess portion 66A for positioning the word line driver circuit microchip 63A and a recess portion (not shown) for positioning the bit line driver circuit microchip 64A are formed around the recess portion 65A. Each of the microchips 62A and 63A is positioned in each recess portion and integrated on the substrate 61.

It is preferable to form the substrate 61 by transfer molding a photocurable resin so that the substrate 61 can be fabricated at low cost.

An example of a method of fabricating the ferroelectric memory having the above structure according to the seventh embodiment is described below.

The passive matrix array microchip 62A, the word line driver circuit microchip 63A, and the bit line driver circuit microchip 64A, each having a different shape, are provided. The recess portions 65A and 66A for positioning each of the microchips 62A to 64A are formed in the substrate 61.

Each of the microchips 62A to 64A is positioned (arranged) in each corresponding recess portion formed in the substrate 61.

The microchips 62A to 64A are preferably arranged in each corresponding recess portion formed in the substrate 61 by applying fluid containing the microchips 62A to 64A to the surface of the substrate 61.

After forming an insulating sealing film 68 on the microchips 62A to 64A, the microchips 62A to 64A are integrated on the substrate 61 through specific processing including electrically connecting the word line driver circuit microchip 63A and the like to the passive matrix array microchip 62A through wiring 69.

As described above, according to the seventh embodiment, the passive matrix array and the peripheral circuits therefor can be separately fabricated. Therefore, the peripheral circuits are not adversely affected when fabricating the passive matrix array, thereby decreasing the degree of limitation in the fabrication process.

According to the seventh embodiment, the passive matrix array and the peripheral circuits are formed using the microchips 62A to 64A each having a different shape. Each of the microchips 62A to 64A is positioned in each corresponding recess portion formed in the substrate 61. Therefore, the microchips 62A to 64A can be mounted on the substrate 61 at the same time by applying fluid containing the microchips 62A to 64A to the surface of the substrate 61.

In the seventh embodiment, the substrate 61 can be fabricated at low cost by forming the substrate 61 by transfer molding a photocurable resin.

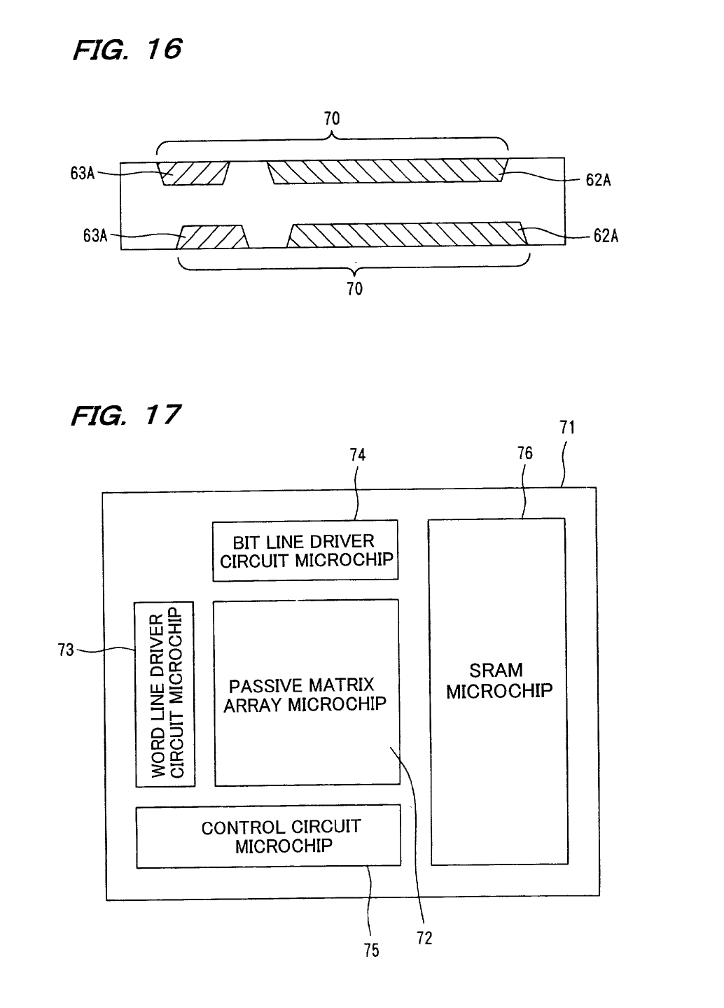

An eighth embodiment of the ferroelectric memory of the present invention is described below with reference to FIG. 16.

The ferroelectric memory according to the eighth embodiment includes a pair of ferroelectric memories 70, each of which consists of the passive matrix array microchip 62A, the word line driver circuit microchip 63A, and the bit line driver circuit microchip 64A of the seventh embodiment shown in FIG. 14. Each of the microchips 62A to 64A of one of the pair of ferroelectric memories 70 is integrated on the front face of the substrate 61, as shown in FIG. 16. Each of the microchips 62A to 64A of the other ferroelectric memory 70 is integrated on the back face of the substrate 61.

The fabrication method for the seventh embodiment is applicable to the fabrication method for the eighth embodiment. Therefore, description thereof is omitted.

As described above, according to the eighth embodiment, each of the passive matrix array and the like are formed by microchips, and each of these microchips is disposed on either the front face or the back face of the substrate 61. Therefore, not only can the degree of limitation in the fabrication process be decreased, but also a large-capacity, large-scale ferroelectric memory can be fabricated.

A ninth embodiment of the ferroelectric memory of the present invention is described below with reference to FIG. 17.

In the ferroelectric memory according to the ninth embodiment, a plurality of microchips which make up the ferroelectric memory and an SRAM microchip 76 which makes up an SRAM having the same function as the ferroelectric memory are integrated on a substrate 71, as shown in FIG. 17. A plurality of microchips which make up the ferroelectric memory consists of a passive matrix array microchip 72, a word line driver circuit microchip 73, a bit line driver circuit microchip 74, and a control circuit microchip 75, as shown in FIG. 17.

The passive matrix array microchip 72, the word line driver circuit microchip 73, and the bit line driver circuit microchip 74 respectively correspond to the passive matrix array microchip 62, the word line driver circuit microchip 63, and the bit line driver circuit microchip 64 shown in FIG. 10. The control circuit microchip 75 is a microchip of a control circuit. The SRAM microchip 76 is a microchip of an SRAM.

In the above example, a plurality of microchips which make up the ferroelectric memory and the SRAM microchip 76 which makes up an SRAM having the same function as the ferroelectric memory are integrated on the substrate 71. However, the SRAM microchip 76 may be replaced by a microchip of specific associated circuits having a function differing from the ferroelectric memory. The present embodiment may be applied to a structure in which circuits having different functions such as a passive matrix array and a bit line driver circuit are integrated in a single microchip.

An example of a method of fabricating the ferroelectric memory having the above structure according to the ninth embodiment is described below.

Each of the microchips 72 to 76 is provided. Recess portions (not shown) for positioning the microchips 72 to 76 are formed in the substrate 71. The microchips 72 to 76 are positioned in each corresponding recess portion formed in the substrate 71. Specific processing, including electrically connecting specific microchips 72 to 76, is performed, thereby integrating these microchips on the substrate 71.

As described above, according to the ninth embodiment, the passive matrix array, the peripheral circuits therefor, and the SRAM can be separately fabricated. Therefore, the peripheral circuits are not adversely affected when fabricating the passive matrix array, thereby decreasing the degree of limitation in the fabrication process.

According to the ninth embodiment, since specific associated circuits having a function either the same or different from the ferroelectric memory are provided, a ferroelectric memory with added value can be fabricated.

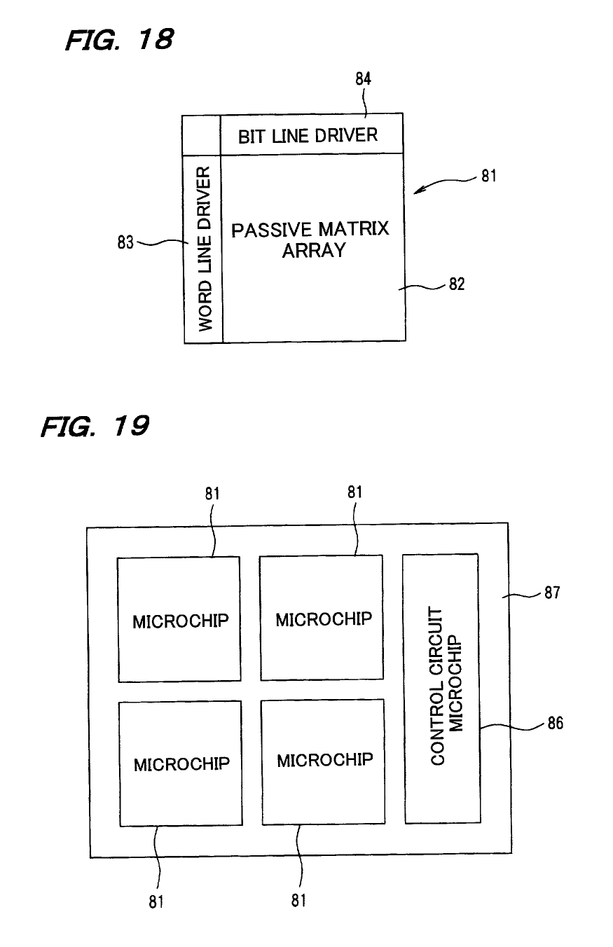

A tenth embodiment of the ferroelectric memory of the present invention is described below with reference to FIG. 18.

In the ferroelectric memory according to the tenth embodiment, a passive matrix array 82, a word line driver circuit 83, and a bit line driver circuit 84 are integrated in a single microchip 81, as shown in FIG. 18. The word line driver circuit 83 and the bit line driver circuit 84 are peripheral circuits which perform data read or write operations for each memory cell of the passive matrix array 82.

As described above, according to the tenth embodiment, since the passive matrix array and the peripheral circuits are integrated in the single microchip 81, steps in wiring between the passive matrix array and the peripheral circuits can be eliminated. This decreases the wiring length, whereby a ferroelectric memory capable of performing high-speed read or write operations can be fabricated.

An eleventh embodiment of the ferroelectric memory of the present invention is described below with reference to FIG. 19.

The ferroelectric memory according to the eleventh embodiment includes a plurality of (four in this example) microchips 81 of the tenth embodiment shown in FIG. 18. A plurality of microchips 81 and a control circuit microchip 86 are integrated on a substrate 87.

The control circuit microchip 86 is a microchip of a control circuit for controlling memory cells of the passive matrix array in the microchips 81 and the like.

Recess portions (not shown) for positioning a plurality of microchips 81 and the control circuit microchip 86 are formed in the substrate 87. A plurality of microchips 81 and the control circuit microchip 86 are positioned in each recess portion, whereby each of these microchips is integrated on the substrate 87.

An example of a method of fabricating the ferroelectric memory having the above structure according to the eleventh embodiment is described below.

Each of a plurality of microchips 81 and the control circuit microchip 86 is provided. Recess portions (not shown) for positioning the microchips 81 and 86 are formed in the substrate 87. The microchips 81 and 86 are positioned in each corresponding recess portion formed in the substrate 87. Specific processing, including electrically connecting specific microchips 81 and 86, is performed, whereby these microchips are integrated on the substrate 87.

As described above, according to the eleventh embodiment, since a plurality of microchips 81 is integrated on the substrate 87, a large-scale, large-capacity ferroelectric memory capable of performing high-speed operation can be fabricated.

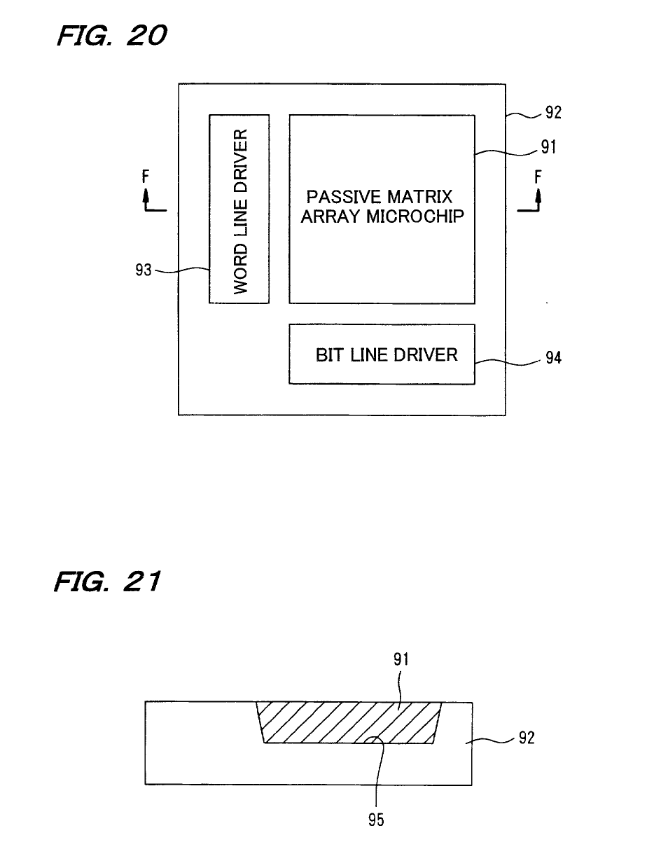

A twelfth embodiment of the ferroelectric memory of the present invention is described below with reference to FIGS. 20 and 21.

In the ferroelectric memory according to the twelfth embodiment, a passive matrix array microchip 91 is integrated in a peripheral circuit microchip 92, as shown in FIGS. 20 and 21.

The passive matrix array microchip 91 is a microchip of a passive matrix array. The passive matrix array microchip 91 is positioned and integrated in a recess portion 95 formed at approximately the center of the peripheral circuit microchip 92. A word line driver circuit 93 and a bit line driver circuit (including sense amplifier) 94 are formed around the passive matrix array microchip 91.

An example of a method of fabricating the ferroelectric memory having the above structure according to the twelfth embodiment is described below.

The passive matrix array microchip 91 is provided as the passive matrix array. The recess portion 95 for positioning the passive matrix array microchip 91 is formed at approximately the center of the peripheral circuit microchip 92. The word line driver circuit 93 and the bit line driver circuit 94 are formed around the recess portion 95. The passive matrix array microchip 91 is positioned in the recess portion 95 formed in the peripheral circuit microchip 92. The passive matrix array microchip 91 is integrated on the peripheral circuit microchip 92 through specific processing including electrically connecting the passive matrix array microchip 91 to the word line driver circuit 93 and the like.

As described above, according to the twelfth embodiment, the passive matrix array and the peripheral circuits therefor can be separately fabricated. Therefore, the peripheral circuits are not adversely affected when fabricating the passive matrix array, thereby decreasing the degree of limitation in the fabrication process.

According to the twelfth embodiment, since the passive matrix array microchip 91 is positioned and integrated in part of the peripheral circuit microchip 92, miniaturization of the ferroelectric memory can be achieved. In addition, a plurality of peripheral circuit microchips 92 in which the passive matrix array microchip 91 is positioned in part thereof may be integrated on the substrate to provide a large-capacity ferroelectric memory.

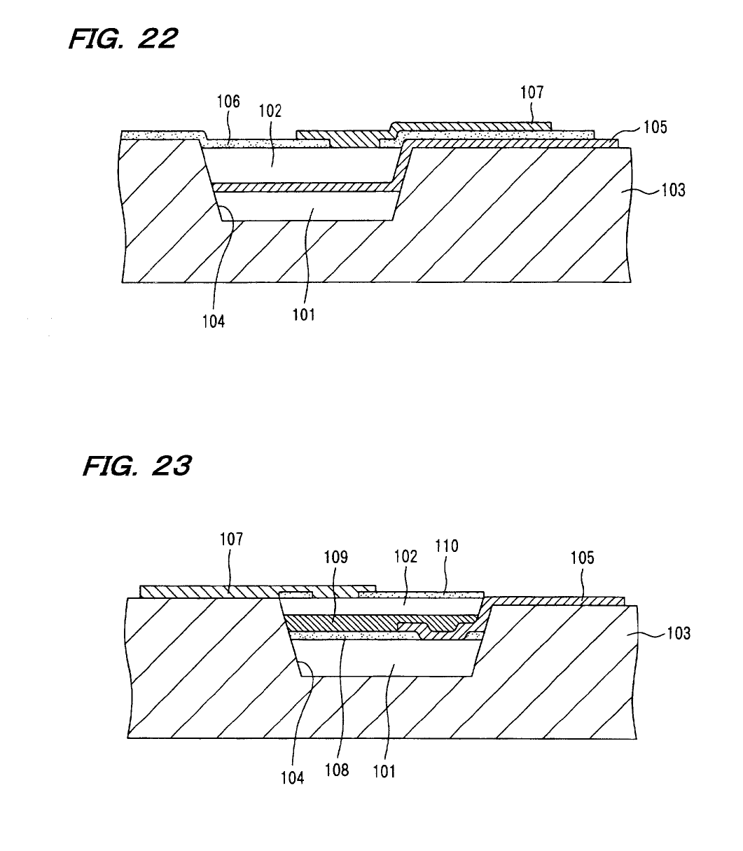

A thirteenth embodiment of the ferroelectric memory of the present invention is described below with reference to FIG. 22.

In the ferroelectric memory according to the thirteenth embodiment, a plurality of (two in this example) passive matrix array microchips 101 and 102 is integrated in layers in a substrate 103, as shown in FIG. 22.

A tapered recess portion 104 is formed in the substrate 103. The passive matrix array microchip 101 is positioned at the bottom of the recess portion 104. Drain wiring 105 is formed on the passive matrix array microchip 101. The passive matrix array microchip 102 is formed on the drain wiring 105. An insulating sealing film 106 is formed on the passive matrix array microchip 102. Drain wiring 107 connected to the passive matrix array microchip 102 is formed on the insulating sealing film 106.

The drain wiring 105 and the drain wiring 107 are connected to specific peripheral circuits (not shown) for the passive matrix array microchips 101 and 102.

An example of a method of fabricating the ferroelectric memory having the above structure according to the thirteenth embodiment is described below.

A plurality of passive matrix array microchips 101 and 102 is provided. After forming the recess portion 104 in the substrate 103, the passive matrix array microchip 101 is positioned in the recess portion 104. The drain wiring 105 is formed on the passive matrix array microchip 101. The passive matrix array microchip 102 is formed on the drain wiring 105. After forming the insulating sealing film 106 on the passive matrix array microchip 102, the passive matrix array microchip 102 is connected to the drain wiring 107.

As described above, according to the thirteenth embodiment, since the passive matrix array microchips 101 and 102 are integrated in layers in the substrate 103, a higher degree of integration can be achieved.

A fourteenth embodiment of the ferroelectric memory of the present invention is described below with reference to FIG. 23.

In the ferroelectric memory according to the fourteenth embodiment, a plurality of passive matrix array microchips 101 and 102 is integrated in layers in the substrate 103 in the same manner as in the thirteenth embodiment shown in FIG. 22. However, the internal structure of the fourteenth embodiment is designed as shown in FIG. 23.

Specifically, the tapered recess portion 104 is formed in the substrate 103. The passive matrix array microchip 101 is positioned at the bottom of the recess portion 104. The passive matrix array microchip 101 is connected to the drain wiring 105. An insulating film 108 is formed on the passive matrix array microchip 101. A planarized film 109 is formed on the insulating film 108. The passive matrix array microchip 102 is formed on the planarized film 109. An insulating film 110 is formed on the passive matrix array microchip 102. The passive matrix array microchip 102 is connected to the drain wiring 107.

An example of a method of fabricating the ferroelectric memory having the above structure according to the fourteenth embodiment is described below.

A plurality of passive matrix array microchips 101 and 102 is provided. The insulating films 108 and 110 with through-holes formed therein have already been formed. After forming the recess portion 104 in the substrate 103, the passive matrix array microchip 101 is positioned in the recess portion 104. The drain wiring 105 is then formed.

After forming the planarized film 109, the passive matrix array microchip 102 is formed on the planarized film 109. The drain wiring 107 is connected to the passive matrix array microchip 102.

As described above, according to the fourteenth embodiment, since the passive matrix array microchips 101 and 102 are integrated in layers in the substrate 103, a higher degree of integration can be achieved.

As described above, according to the inventions according to claims 1 to 3, the passive matrix array and the peripheral circuits therefor can be separately fabricated. Therefore, the peripheral circuits are not adversely affected when fabricating the passive matrix array, thereby decreasing the degree of limitation in the fabrication process.

According to the invention according to claim 4, since the passive matrix array and the like are formed by a plurality of microstructures, not only can the degree of limitation in the fabrication process be decreased, but also a large-capacity, large-scale ferroelectric memory can be fabricated.

According to the invention according to claim 5, the passive matrix array and the like are formed by a plurality of microstructures. These microstructures are positioned in the recess portions formed in the substrate. Therefore, not only can the degree of limitation in the fabrication process be decreased, but also a plurality of microstructures can be mounted on the substrate at the same time.

According to the invention according to claim 6, since the substrate is formed by transfer molding a photocurable resin, the substrate can be formed at low cost.

According to the invention according to claim 7, each of the passive matrix array and the like is formed by microstructures. Each of these microstructure is disposed on either the front face or the back face of the substrate. Therefore, not only can the degree of limitation in the fabrication process be decreased, but also a large-capacity, large-scale ferroelectric memory can be fabricated.

According to the invention according to claim 8, since specific associated circuits having a function either the same or different from that of the ferroelectric memory are provided, a ferroelectric memory with added value can be fabricated. Moreover, since the passive matrix array, the peripheral circuits therefor, and the like can be separately fabricated, the peripheral circuits are not adversely affected when fabricating the passive matrix array, thereby decreasing the degree of limitation in the fabrication process.

According to the invention according to claim 9, since the passive matrix array and the peripheral circuits are integrated in a single microstructure, steps in the wiring between the passive matrix array and the peripheral circuits can be eliminated. This decreases the wiring length, whereby a ferroelectric memory capable of performing high-speed read or write operation can be fabricated.

According to the invention according to claim 10, the passive matrix array and the peripheral circuit are respectively formed by first and second microstructures, wherein the first microstructure is positioned in part of the second microstructure. Therefore, not only can the degree of limitation in the fabrication process be decreased, but also miniaturization of the ferroelectric memory can be achieved.

According to the invention according to claim 11, the passive matrix array is formed by a plurality of microstructures, wherein a plurality of microstructures is integrated in layers in the substrate. Therefore, a higher degree of integration and densification of the passive matrix array can be achieved.

According to the inventions according to claims 12 to 14, since the passive matrix array and the peripheral circuits therefor are independently provided, the peripheral circuits are not adversely affected when fabricating the passive matrix array, thereby decreasing the degree of limitation in the fabrication process.

According to the invention according to claim 15, the passive matrix array and the like are formed by a plurality of microstructures, wherein the microstructures are positioned in the recess portions formed in the substrate. Therefore, not only can the degree of limitation in the fabrication process be decreased, but also a plurality of microstructures can be mounted on the substrate at the same time.

According to the invention according to claim 16, a plurality of microstructures can be mounted on the substrate at the same time.

According to the invention according to claim 17, each of the passive matrix array and the like is formed by a microstructure, wherein each of these microstructures is disposed on either the front face or the back face of the substrate. Therefore, not only can the degree of limitation in the fabrication process be decreased, but also a large-capacity, large-scale ferroelectric memory can be fabricated.

According to the invention according to claim 18, the passive matrix array and the peripheral circuit are respectively formed by first and second microstructures, wherein the first microstructure is positioned in part of the second microstructure. Therefore, not only can the degree of limitation in the fabrication process be decreased, but also miniaturization of the ferroelectric memory can be achieved.

According to the invention according to claim 19, the passive matrix array is formed by a plurality of microstructures, wherein a plurality of microstructures is integrated in layers in the substrate. Therefore, a higher degree of integration and densification of the passive matrix array can be achieved.

What is claimed is:

1. A ferroelectric memory comprising:
a passive matrix array in which memory cells formed of ferroelectric capacitors are arranged; and
a peripheral circuit for the passive matrix array, wherein:
the passive matrix array is formed on a microstructure;
the peripheral circuit is formed on a substrate; and
the microstructure is integrated on the substrate.

2. A ferroelectric memory comprising:
a passive matrix array in which memory cells formed of ferroelectric capacitors are arranged; and
a peripheral circuit for the passive matrix array, wherein:
the passive matrix array is formed on a substrate;
the peripheral circuit is formed on a microstructure; and
the microstructures is integrated on the substrate.

3. A ferroelectric memory comprising:
a passive matrix array in which memory cells formed of ferroelectric capacitors are arranged; and
a peripheral circuit for the passive matrix array, wherein:
the passive matrix array is formed on a first microstructure;
the peripheral circuit is formed on a second microstructure; and
the first and second microstructures are integrated on a substrate.

4. The ferroelectric memory according to claim 1, 2, or 3, wherein a plurality of microstructures is integrated in the case where the passive matrix array is formed on the microstructure, and a plurality of microstructures is integrated in the case where the peripheral circuits are formed on the microstructures.

5. The ferroelectric memory as defined in any one of claims 1 to 4, wherein:
a recess portion in which the microstructure is provided is formed in the substrate; and
the microstructure is provided in the recess portion and integrated on the substrate.

6. The ferroelectric memory as defined in claim 5,
wherein the substrate is formed by transfer-molding a photocurable resin.

7. A ferroelectric memory comprising:
a passive matrix array in which memory cells formed of ferroelectric capacitors are arranged;
a peripheral circuit for the passive matrix array; and
a plurality of pairs of the passive matrix array formed on a first microstructure and the peripheral circuit formed on a second microstructure,
wherein at least one of the pairs is provided on each side of a substrate.

8. A ferroelectric memory comprising:
a passive matrix array in which memory cells formed of ferroelectric capacitors are arranged;
a peripheral circuit for the passive matrix array; and
an associated circuit having the same function as the ferroelectric memory or a different function from the ferroelectric memory, wherein:
the passive matrix array, the peripheral circuit and the associated circuit are formed on each of a plurality of microstructures; and
the microstructures are integrated on a single substrate.

9. A ferroelectric memory comprising:
a passive matrix array in which memory cells formed of ferroelectric capacitors are arranged; and
a peripheral circuit for the passive matrix array,
wherein the passive matrix array and the peripheral circuit are integrated on a single microstructure.

10. A ferroelectric memory comprising:
a passive matrix array in which memory cells formed of ferroelectric capacitors are arranged; and
a peripheral circuit for the passive matrix array, wherein:
the passive matrix array is formed on a first microstructure;
the peripheral circuit is formed on a second microstructure which is larger than the first microstructure; and
the first microstructure is provided in a part of the second microstructure to be integrated.

11. A ferroelectric memory comprising:
a passive matrix array in which memory cells formed of ferroelectric capacitors are arranged; and
a peripheral circuit for the passive matrix array, wherein:
the passive matrix array is formed on each of a plurality of microstructures; and
the microstructures are provided in layers to be integrated in a substrate.

12. A method of fabricating a ferroelectric memory which includes: a passive matrix array in which memory cells formed of ferroelectric capacitors are arranged; and a peripheral circuit for the passive matrix array, wherein:
the passive matrix array is formed on a microstructure;
the peripheral circuit is formed on a substrate; and
the microstructure is integrated on the substrate.

13. A method of fabricating a ferroelectric memory which includes: a passive matrix array in which memory cells formed of ferroelectric capacitors are arranged; and a peripheral circuit for the passive matrix array, wherein:
the passive matrix array is formed on a substrate;
the peripheral circuit is formed on a microstructure; and
the microstructure is integrated on the substrate.

14. A method of fabricating a ferroelectric memory which includes: a passive matrix array in which memory cells formed of ferroelectric capacitors are arranged; and a peripheral circuit for the passive matrix array, wherein:
the passive matrix array is formed on a first microstructure;
the peripheral circuit is formed on a second microstructure; and
the first and second microstructures are integrated on a substrate.

15. The method of fabricating a ferroelectric memory as defined in any one of claims 12 to 14, wherein:
a substrate having a recess portion which corresponds to a shape of the microstructure is provided; and
the microstructure is provided in the corresponding recess portion in the substrate to be integrated.

16. The method of fabricating a ferroelectric memory as defined in claim 15,
wherein the microstructure is provided in the recess portion in the substrate by providing a fluid which contains the microstructure to a surface of the substrate.

17. A method of fabricating a ferroelectric memory which includes: a passive matrix array in which memory cells formed of ferroelectric capacitors are arranged; and a peripheral circuit for the passive matrix array, wherein:
a plurality of pairs of the passive matrix array formed on a first microstructure and the peripheral circuit formed on a second microstructure are provided: and
at least one of the pairs is integrated on each side of a substrate.

18. A method of fabricating a ferroelectric memory, which includes: a passive matrix array in which memory cells formed of ferroelectric capacitors are arranged; and a peripheral circuit for the passive matrix array, wherein:
the passive matrix array is formed on a first microstructure;
the peripheral circuit is formed on a second microstructure which is larger than the first microstructure; and
the first microstructure is provided in a part of the second microstructure to be integrated.

19. A method of fabricating a ferroelectric memory, which includes: a passive matrix array in which memory cells formed of ferroelectric capacitors are arranged; and a peripheral circuit for the passive matrix array, wherein:
the passive matrix array is formed on each of a plurality of microstructures; and
the microstructures are provided in layers to be integrated in a substrate.
